(19) United States
(12) Patent Application Publication
(10) Pub. No.: US 2015/0253674 A1
(43) Pub. Date: Sep. 10, 2015

(54) EXPOSURE APPARATUS, EXPOSURE METHOD AND MANUFACTURING METHOD OF SEMICONDUCTOR DEVICE

(71) Applicant: Kabushiki Kaisha Toshiba, Minato-ku (JP)

(72) Inventors: Satoshi NAGAI, Yokkaichi-shi (JP); Eiji YONEDA, Yokkaichi-shi (JP)

(73) Assignee: Kabushiki Kaisha Toshiba, Minato-ku (JP)

(21) Appl. No.: 14/311,615

(22) Filed: Jun. 23, 2014

Related U.S. Application Data
(60) Provisional application No. 61/950,527, filed on Mar. 10, 2014.

(51) Int. Cl. G03F 7/20; H01L 21/02

(52) U.S. Cl. CPC G03F 7/7015; H01L 21/02348

(57) ABSTRACT

According to one embodiment, a resist film formed on a processing layer is exposed by irradiating exposure light with a first wavelength belonging to an EUV band and auxiliary light with a second wavelength different from the first wavelength, the auxiliary light being separately generated from the exposure light.

### CROSS-REFERENCE TO RELATED APPLICATIONS

This application is based upon and claims the benefit of priority from Provisional Patent Application No. 61/950,527, filed on Mar. 10, 2014; the entire contents of which are incorporated herein by reference.

### FIELD

Embodiments described herein relate generally to an exposure apparatus, an exposure method, and a manufacturing method of a semiconductor device.

### BACKGROUND

In recent years, there have been increased expectations for EUV lithographical techniques as next-generation lithographical means for further finer patterning of a semiconductor circuit. In EUV lithography, EUV light with a wavelength of 13.5 nm can be used as exposure light to form a fine pattern that cannot be realized by liquid-immersion exposure using light with a wavelength of 193 nm.

### BRIEF DESCRIPTION OF THE DRAWINGS

FIG. 1 is a schematic perspective view of an EUV exposure device according to a first embodiment;

FIG. 2A is a plane view of one example of a design pattern exposed to a wafer W illustrated in FIG. 1, and FIG. 2B is a plane view of one example of a mask pattern exposed to the wafer W illustrated in FIG. 1;

FIG. 3A is a plane view of one example of a resist pattern formed on the wafer W illustrated in FIG. 1, FIG. 3B is a cross-sectional view of one example of the resist pattern formed on the wafer W illustrated in FIG. 1, and FIG. 3C is a cross-sectional view of one example of a process pattern formed on the wafer W illustrated in FIG. 1;

FIG. 4 is a diagram illustrating the relationship between MUV exposure amount and measured dimension of a resist pattern according to the first embodiment;

FIG. 5 is a diagram illustrating a setting method of auxiliary light with respect to out-of-band light according to the first embodiment;

FIG. 6 is a flowchart of one example of a lithography process in which the EUV exposure device according to the first embodiment is used;

FIGS. 7A and 7B are cross-sectional diagrams illustrating an EUV exposure method according to a second embodiment, and FIG. 7C is a diagram illustrating the relationship between x position and acid concentration in the EUV exposure method according to the second embodiment;

FIGS. 8A and 8B are plane views of examples of mask patterns applied to the EUV exposure method according to the second embodiment;

FIG. 9 is a block diagram of an exposure system configuration applied to an EUV exposure method according to a third embodiment;

FIG. 10 is a schematic perspective view of a developing device applied to the EUV exposure method according to the third embodiment;

FIG. 11 is a diagram illustrating a setting method of auxiliary light with respect to out-of-band light according to the third embodiment; and

FIG. 12 is a flowchart of one example of a lithography process in which the EUV exposure method according to the third embodiment is used.

### DETAILED DESCRIPTION

In general, according to one embodiment, exposure light with a first wavelength belonging to an EUV band and auxiliary light, generated separately from the exposure light, with a second wavelength different from the first wavelength are irradiated to form a resist film on a processing layer.

Exemplary embodiments of an exposure device, an exposure method, and a manufacturing method of a semiconductor device will be explained below in detail with reference to the accompanying drawings. The present invention is not limited to the following embodiments.

### First Embodiment

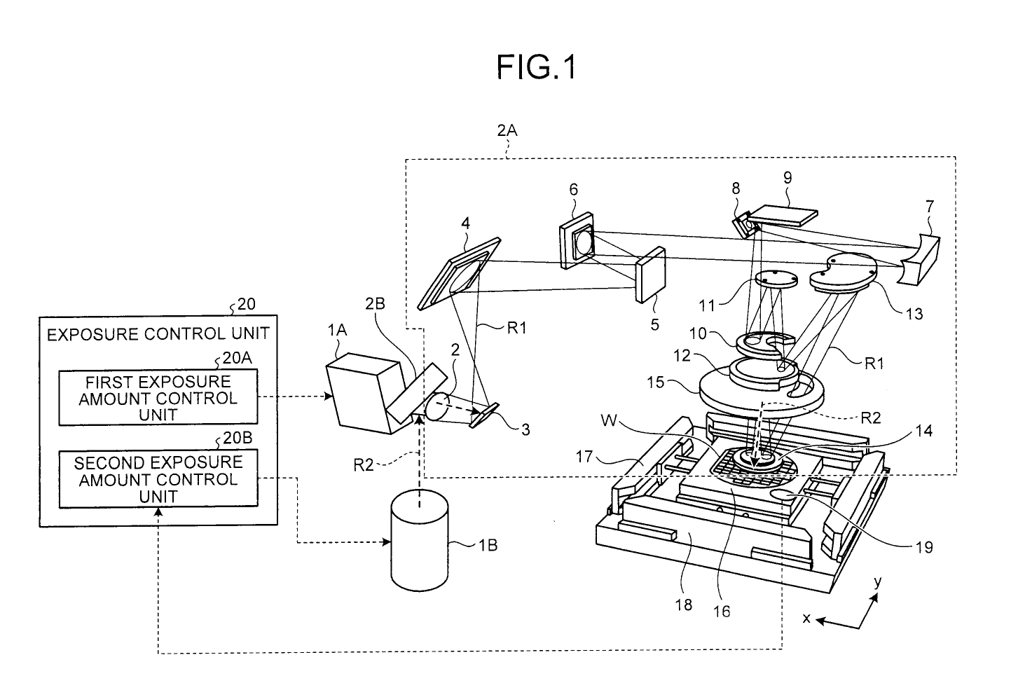

FIG. 1 is a schematic perspective view of an EUV exposure device according to a first embodiment.

Referring to FIG. 1, the EUV exposure device is provided with a first light source 1A that generates exposure light R1, a first optical system 2A that guides the exposure light R1 emitted from the first light source 1A to a wafer W via a reticle 9, a second light source 1B that generates auxiliary light R2, a second optical system 2B that guides the auxiliary light R2 emitted from the second light source 1B to the wafer W via the reticle 9, and a wafer stage 16 on which the wafer W is placed. The second optical system 2B may use a part of the first optical system 2A. In the example of FIG. 1, a reflective element is provided to guide the auxiliary light R2 to the first optical system 2A as the second optical system 2B. The reticle 9 can be set at the first optical system 2A. A mask pattern corresponding to a layout pattern to be projected onto the wafer W can be formed on the reticle 9. The reticle 9 may be a mirror plate that reflects the exposure light R1 and the auxiliary light R2, and the mirror plate is provided with a light-absorption pattern to form a mask pattern. The mirror plate may be a multi-layer reflective film formed by an Mo/Si multi-layer film, for example. A Ta-based material may be used in the light-absorption pattern.

Light with a first wavelength belonging to an EUV band (extreme ultra violet) (hereinafter, also referred to as EUV light) may be used as the exposure light R1. The first wavelength can be set to 6.5 or 13.5 nm, for example. The exposure light R1 contains out-of-band (OoB) light. The out-of-band light has an out-of-band wavelength different from the first wavelength. The out-of-band wavelength falls within a range of 10 to 400 nm. The auxiliary light R2 has a second wavelength different from the first wavelength. The second wavelength of the auxiliary light R2 can be set within a range of 10 to 400 nm, for example. In addition, a wavelength corresponding to the out-of-band light of the exposure light R1 can be selected as the second wavelength of the auxiliary light R2.

The generating mode of the EUV light may be laser-produced plasma (LPP) mode by which laser light is irradiated to a target substance such as atoms of Sn or the like, or laser-assisted discharge plasma (LDP) mode by which laser light is emitted as a trigger with electrical discharged under a high voltage. The out-of-band light produced during generation of the EUV light refers to light with a wavelength that is generally in a ultra-violet band and is not an ideal wavelength for the exposure light R1 of the EUV exposure. The out-of-band light may be generated concurrently with the EUV light at a stage of Sn-atom plasma emission as a generation source of the EUV light. In addition, at the light source in the LPP mode, the out-of-band light may result from scattered light from a CO₂ laser playing the role of a trigger for forming plasma of Sn atoms. The out-of-band light may deteriorate resolving power of the resist film on the wafer W.

The first optical system 2A is provided with a collector mirror 2 and reflective elements 3 to 8 and 10 to 15. A light sensor 19 is provided on the wafer stage 16 to detect the auxiliary light R2 and the out-of-band light of the exposure light R1.

In addition, the EUV exposure device is provided with drive units 17 and 18 that move the wafer stage 16 within a horizontal plane (in x and y directions) and vertical direction z. The EUV exposure device is also provided with an exposure control unit 20. The exposure control unit 20 includes a first exposure amount control unit 20A that controls exposure amount of the exposure light R1, and a second exposure amount control unit 20B that controls exposure amount of the auxiliary light R2. The second exposure amount control unit 20B can control the exposure amount of the auxiliary light R2 based on the exposure amount of the out-of-band light of the exposure light R1. At that time, the second exposure amount control unit 20B may control the exposure amount of the auxiliary light R2 such that the exposure amount of the out-of-band light of the exposure light R1 and the exposure amount of the auxiliary light R2 are kept constant.

Then, the exposure light R1 generated from the first light source 1A is collected by the collector mirror 2, and then is guided to the reticle 9 via the reflective elements 3 to 8. Then, the exposure light R1 reflected on the reticle 9 is projected onto the wafer W via the reflective elements 10 to 15. A resist film sensitive to the exposure light R1 can be formed on the wafer W.

Meanwhile, the auxiliary light R2 generated from the second light source 1B is guided to the reflective element 3 via the second optical system 2B, and guided to the reticle 9 via the reflective elements 4 to 8. Then, the auxiliary light R2 reflected on the reticle 9 is projected onto the wafer W via the reflective elements 10 to 15.

Here, after the exposure light R1 is projected onto the wafer W, the wafer stage 16 can be moved such that the exposure light R1 is projected onto the light sensor 19. Then, the intensity and irradiation time of the exposure light R1 are set so as to be the same as those at the projection onto the wafer W. Then, the light sensor 19 measures the exposure amount of the out-of-band light of the exposure light R1.

In addition, before the auxiliary light R2 is projected onto the wafer W, the wafer stage 16 can be moved such that the auxiliary light R2 is projected onto the light sensor 19. Then, the light sensor 19 measures the exposure amount of the auxiliary light R2. The intensity and irradiation time of the auxiliary light R2 can be set to compensate for fluctuations in the exposure amount of the out-of-band light of the exposure light R1 detected by the light sensor 19. The exposure light R1 and the auxiliary light R2 may be simultaneously irradiated to the resist film on the wafer W, or after irradiation of the exposure light R1 to the resist film on the wafer W, the auxiliary light R2 may be irradiated to the resist film on the wafer W.

Then, when the exposure light R1 and the auxiliary light R2 are irradiated to the wafer W, the resist film on the wafer W can be developed to form a resist pattern corresponding to the design pattern on the wafer W.

By irradiating the auxiliary light R2 to the wafer W, even when the exposure amount of the out-of-band light of the exposure light R1 irradiated to the wafer W fluctuates due to temporal changes in intensity of the out-of-band light of the exposure light R1 and the like, the fluctuations in the exposure amount of the out-of-band light of the exposure light R1 can be compensated for. Accordingly, it is possible to reduce dimensional variations of the resist pattern due to fluctuations in the exposure amount of the out-of-band light of the exposure light R1 and improve the dimension accuracy of the resist pattern.

The causes of temporal changes in intensity of the out-of-band light of the exposure light R1 include: when the EUV exposure device is operated within a time scale of several months to several years, the surface of the collector mirror 2 deteriorates under irradiation of the EUV light; debris become deposited on the surface of the collector mirror 2; and in the optical system of the EUV exposure device including a mask or a pellicle, the surfaces of mirrors other than the collector mirror 2 existing in the light path of the EUV light deteriorate under irradiation of the EUV light.

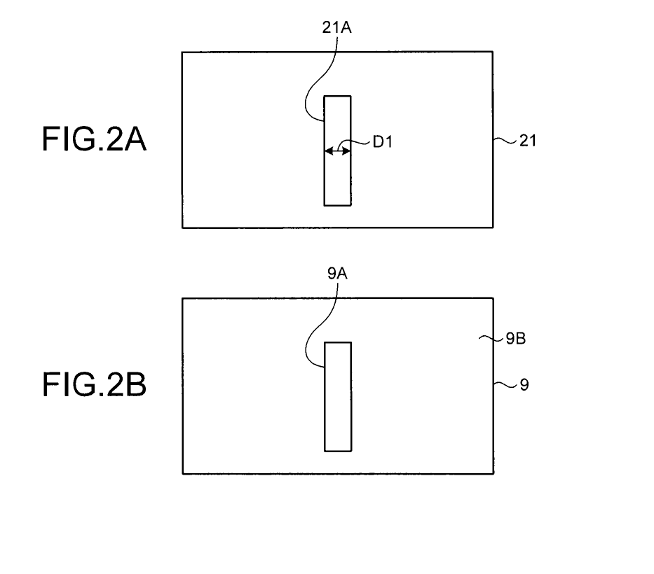

FIG. 2A is a plane view of one example of a design pattern exposed to a wafer W illustrated in FIG. 1, and FIG. 2B is a plane view of one example of a mask pattern exposed to the wafer W illustrated in FIG. 1.

Referring to FIG. 2A, a design pattern 21A of a designed dimension D1 is formed on a wafer surface 21. The designed dimension D1 can be set to 20 nm, for example. At that time, the reticle 9 includes a light-absorption film 9B. Then, by patterning the light-absorption film 9B corresponding to the design pattern 21A, it is possible to form a reflective pattern 9A of the same size as the design pattern 21A. The reticle 9 can be used to irradiate the exposure light R1 and the auxiliary light R2 to the wafer W.

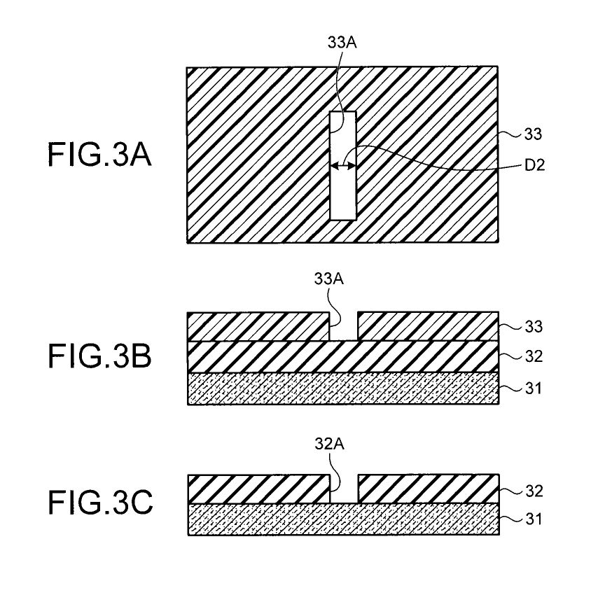

FIG. 3A is a plane view of one example of a resist pattern formed on the wafer W illustrated in FIG. 1, FIG. 3B is a cross-sectional view of one example of the resist pattern formed on the wafer W illustrated in FIG. 1, and FIG. 3C is a cross-sectional view of one example of a process pattern formed on the wafer W illustrated in FIG. 1.

Referring to FIGS. 3A and 3B, a processing layer 32 is formed on a foundation layer 31, and a resist film 33 is formed on the processing layer 32. After the exposure light R1 and the auxiliary light R2 are irradiated to the resist film 33 via the reticle 9, the resist film 33 can be developed to form a resist pattern 33A corresponding to the design pattern 21A on the resist film 33. At that time, a measured dimension D2 of the resist pattern 33A can be made equal to the designed dimension D1. There is no particular limit on the foundation layer 31 and the processing layer 32, and the foundation layer 31 and the processing layer 32 may be a semiconductor substrate, or may be insulating layers or conductive layers formed on the semiconductor substrate.

Next, as illustrated in FIG. 3C, when the processing layer 32 is processed via the resist film 33 on which the resist pattern 33A is formed, a process pattern 32A corresponding to the resist pattern 33A is formed on the processing layer 32. Processing of the processing layer 32 may be etching or ion implantation.

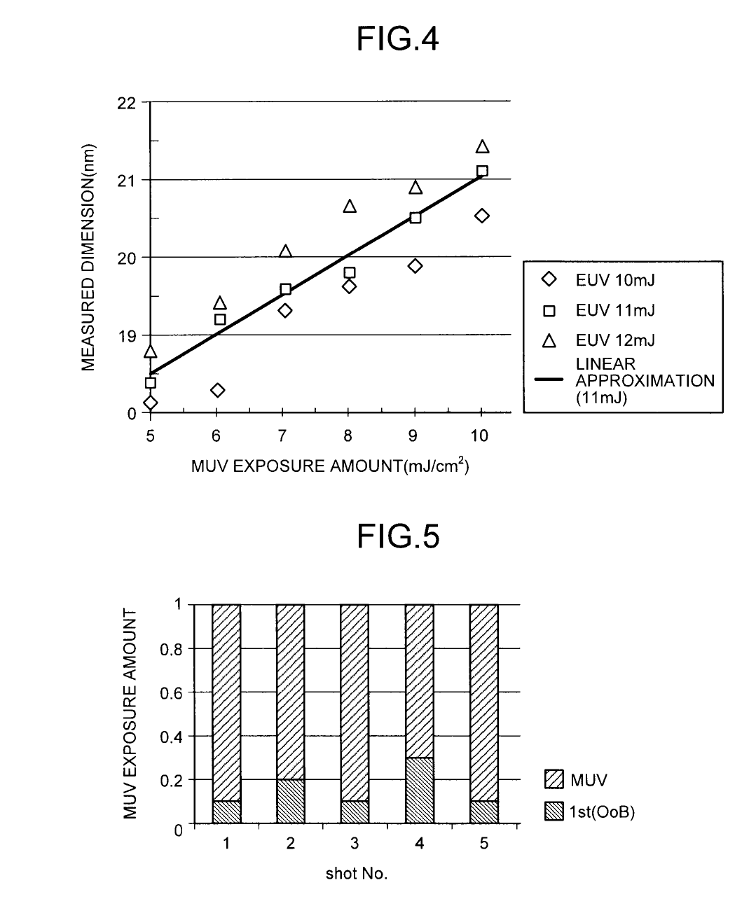

FIG. 4 is a diagram illustrating the relationship between MUV exposure amount and measured dimension of a resist pattern according to the first embodiment. In the example of FIG. 4, the exposure amount of the out-of-band light involved in the EUV light is set as MUV exposure amount.

Referring to FIG. 4, when the EUV exposure amount increases (for example, 10 mJ→11 mJ→12 mJ), the measured dimension D2 increases. Meanwhile, when the MUV exposure amount increases while the EUV exposure amount is kept constant, the measured dimension D2 increases. Here, it can be regarded that the MUV exposure amount and the measured dimension D2 are in linear relationship. For example, when the EUV exposure amount is 11 mJ, the relationship between MUV exposure amount p and measured dimension q can be expressed by linear approximation by equation of q=0.5029×p+15.995.

In addition, when the EUV exposure amount is 11 mJ, it is assumed that the MUV exposure amount is 9 mJ and the measured dimension is 20.5 nm. Then, when the designed dimension D1 is 20 nm, for example, the MUV exposure amount is determined as 7.96 mJ according to the relationship illustrated in FIG. 4. By adjusting the MUV exposure amount by the auxiliary light R2 according to the method, the measured dimension D2 can be made equal to the designed dimension D1.

FIG. 5 is a diagram illustrating a setting method of auxiliary light with respect to out-of-band light according to the first embodiment.

Referring to FIG. 5, when the intensity of the out-of-band (OoB) light in the EUV light fluctuates depending on shot numbers, by setting the exposure amount of the MUV light to compensate for the fluctuations, it is possible to reduce differences in measured dimension between the shots. FIG. 5 recites a method of compensating for the fluctuations in the OoB light intensity depending on the shot numbers. However, the method is not limited to the compensation of differences between shots, and the method may compensate for differences in measured dimension in a shot, differences in measured dimension between wafers, or differences in measured dimension between lots. In that case, the exposure amount of the MUV light can be set to compensate for fluctuations between lots, wafers, or shots, or fluctuations in a shot.

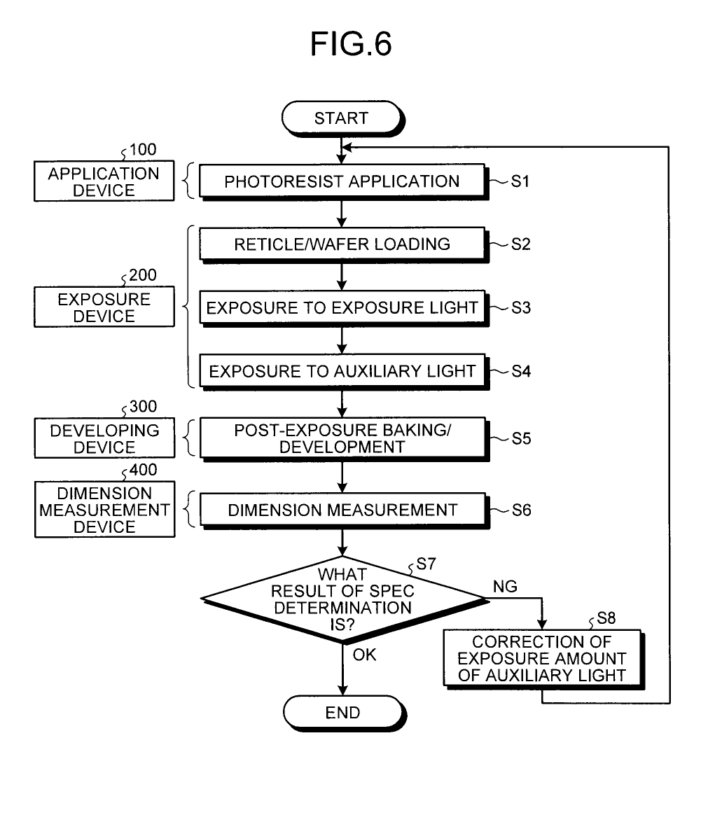

FIG. 6 is a flowchart of one example of a lithography process in which the EUV exposure device according to the first embodiment is used.

Referring to FIG. 6, a photoresist is applied to the wafer W by an application device 100 (S1). Then, the reticle 9 and the wafer W are loaded to an exposure device 200 (S2). Then, the exposure light R1 is irradiated to the photoresist on the wafer W by predetermined exposure amount to expose the photoresist on the wafer W (S3). In addition, the auxiliary light R2 is irradiated to the photoresist on the wafer W to compensate for fluctuations in the out-of-band light of the exposure light R1 (S4). Then, a developing device 300 performs post-exposure baking and development to form a resist pattern on the wafer W (S5). Then, a dimension measurement device 400 measures a dimension of the resist pattern on the wafer W (S6). The dimension measurement device 400 may be a CD-SEM (critical dimension SEM), for example. Then, it is determined whether the dimension of the resist pattern on the wafer W falls within a specified range (S7). When the dimension does not fall within the specified range, the exposure amount of the auxiliary light R2 is corrected (S8) and the process is returned to S1. Then, steps S1 to S8 are repeated until the dimension of the resist pattern on the wafer W falls within the specified range.

### Second Embodiment

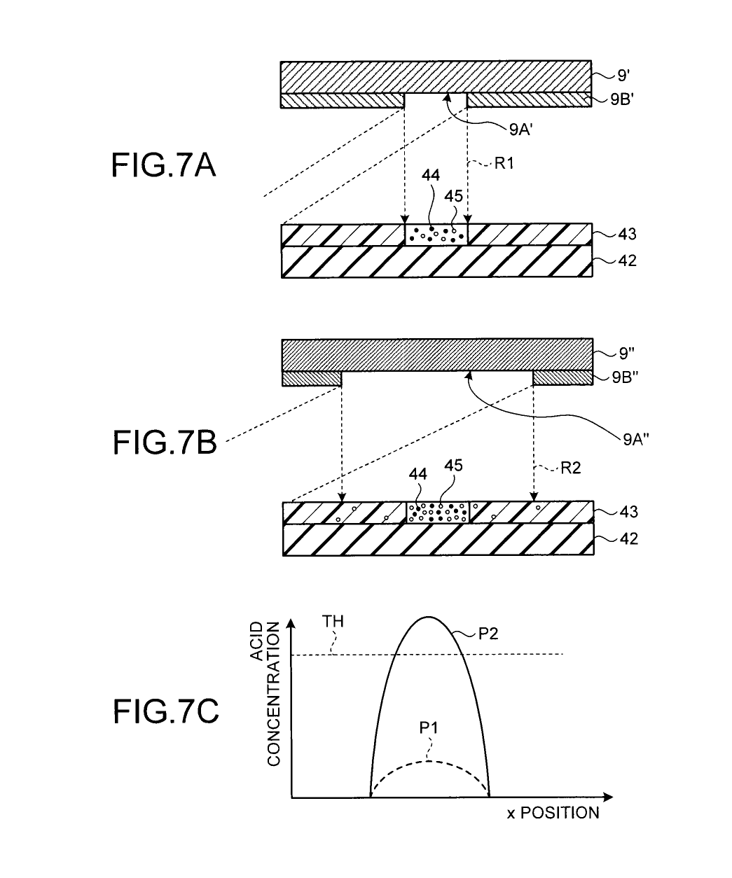

FIGS. 7A and 7B are cross-sectional diagrams illustrating an EUV exposure method according to a second embodiment, and FIG. 7C is a diagram illustrating the relationship between x position and acid concentration in the EUV exposure method according to the second embodiment.

Referring to FIG. 7A, a reticle 9′ is provided with a light-absorption film 9B′. The light-absorption film 9B′ can be patterned to form a reflective pattern 9A′. Meanwhile, a processing layer 42 is provided with a photosensitive resist film 43. The photosensitized resist refers to a resist containing a catalytic component called a photosensitizer to facilitate reaction of the resist with light to form acid. In this example, the acid-forming reaction is caused by the out-of-band light, and the photosensitizer itself is generated by irradiating the EUV light to the resist. In the resist widely used in general EUV exposure, acid is formed according to the pattern of EUV light and thus the pattern of the EUV light becomes a developed pattern as it is, whereas, by using the resist, both distributions of the out-of-band light and the EUV light relate to formation of the pattern. Thus, it is necessary to control the both distributions of the out-of-band light and the EUV light at high accuracy.

Then, the exposure light R1 incident on the reticle 9′ is reflected by the reflective pattern 9A′ and irradiated to the photosensitive resist film 43. At that time, a photosensitizer 44 is generated at a portion of the photosensitive resist film 43 irradiated by the exposure light R1. At the same time, a certain amount of acid 45 is also generated. The concentration of the acid 45 at that time can be expressed by P1 in FIG. 7C. In FIG. 7C, TH denotes a threshold value of concentration of the acid 45 necessary for resolution of the photosensitive resist film 43.

In addition, referring to FIG. 7B, a reticle 9″ is provided with a light-absorption film 9B″. The absorption film 9B″ can be patterned to form a reflective pattern 9A″. The reflective patterns 9A′ and 9A″ may not necessarily be equal to each other and may be different from each other.

Then, the auxiliary light R2 incident on the reticle 9″ is reflected by the reflective pattern 9A″ and irradiated to the photosensitive resist film 43. At that time, the acid 45 is grown by catalytic action of the photosensitizer 44. With the growth of the acid 45, the concentration of the acid 45 at the portion with the photosensitizer 44 can be made higher than that at the portion without the photosensitizer 44, in some cases, by the degree of 10 times or more. The concentration of the acid 45 at that time can be expressed by P2 in FIG. 7C.

Thus, even when the concentration of the acid 45 necessary for resolution of the photosensitive resist film 43 cannot be obtained only by irradiation of the exposure light R1 due to insufficient intensity, the auxiliary light R2 can be irradiated after the irradiation of the exposure light R1 to obtain the concentration of the acid 45 necessary for resolution of the photosensitive resist film 43 only at the portion irradiated by the exposure light R1. Accordingly, even when the intensity of the exposure light R1 is low, it is possible to improve throughput in EUV lithography.

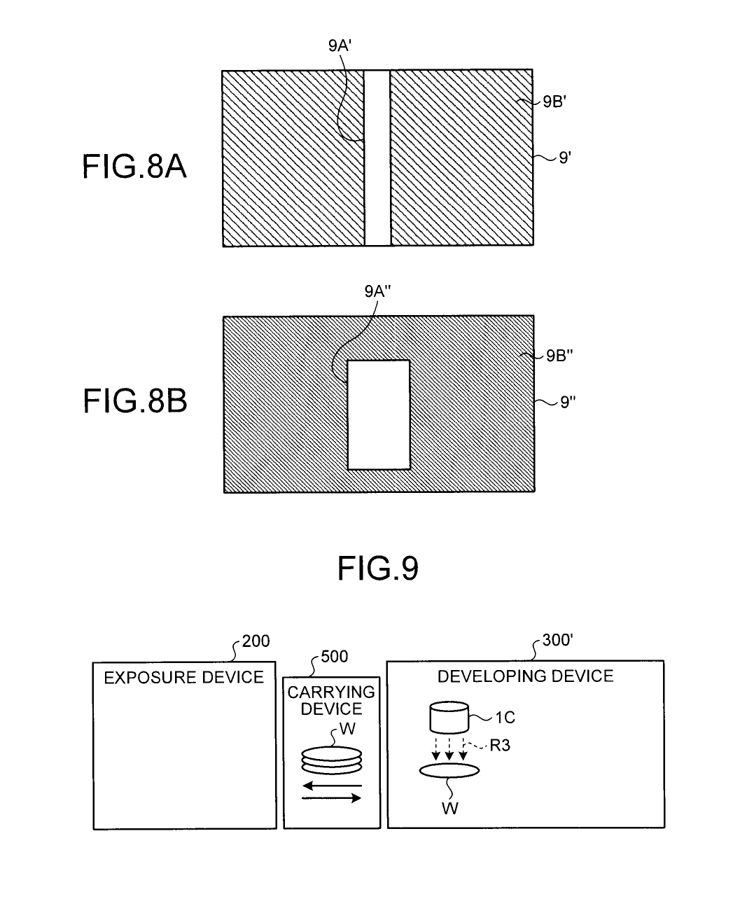

FIGS. 8A and 8B are plane views of examples of mask patterns applied to the EUV exposure method according to the second embodiment.

The pattern to be developed by exposure using the masks illustrated in FIGS. 8A and 8B is the same as the design pattern 21A illustrated in FIG. 2A. In this example, on the photosensitive resist film 43 illustrated in FIG. 7A, an overlapping portion between the reflective patterns 9A′ and 9A″ can be equal to the design pattern 21A to resolve the photosensitive resist film 43 in correspondence with the design pattern 21A.

### Third Embodiment

FIG. 9 is a block diagram of an exposure system configuration applied to an EUV exposure method according to a third embodiment.

Referring to FIG. 9, the exposure system is provided with an exposure device 200, a carrying device 500, and a developing device 300′. The exposure device 200 can be configured in the same manner as illustrated in FIG. 1. The carrying device 500 can carry the wafer W out of the exposure device 200 into the developing device 300′. The developing device 300′ can develop a resist film exposed to light at the exposure device 200. The developing device 300′ can be provided with a third light source 1C generating auxiliary light R3. The auxiliary light R3 has a third wavelength different from the first wavelength of the exposure light R1. The third wavelength of the auxiliary light R3 can be set within a range of 10 to 400 nm, for example. As the third wavelength of the auxiliary light R3, a wavelength corresponding to the out-of-band light of the exposure light R1 can be selected. The third wavelength of the auxiliary light R3 can be equal to the second wavelength of the auxiliary light R2.

Then, when the exposure light R1 and the auxiliary light R2 are irradiated to the resist film on the wafer W, the wafer W is carried into the developing device 300′ via the carrying device 500. Then, after the auxiliary light R3 is irradiated to the wafer W at the developing device 300′, the resist film on the wafer W is developed. The exposure amount of the auxiliary light R3 can be controlled such that the sum of the exposure amount of the out-of-band light of the exposure light R1 and the exposure amounts of the auxiliary lights R2 and R3 are kept constant. At that time, the auxiliary light R2 may not be irradiated after the irradiation of the exposure light R1 at the exposure device 200 but the auxiliary light R3 may be irradiated at the developing device 300′.

By irradiating the auxiliary light R3 at the developing device 300′, it is possible to set the irradiation amount of the auxiliary light R2 at the exposure device 200 as low as possible and thus to improve process efficiency of the exposure device 200.

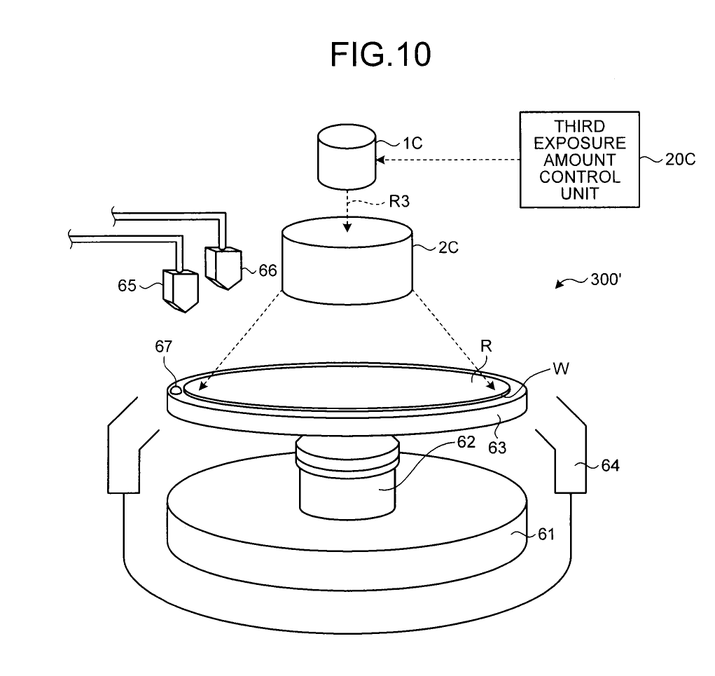

FIG. 10 is a schematic perspective view of a developing device applied to the EUV exposure method according to the third embodiment.

Referring to FIG. 10, the developing device 300′ is provided with a wafer holder 63 that holds the wafer W with a resist film R, a support stand 61 that supports the wafer holder 63, a motor 62 that rotates the wafer holder 63, a cup 64 that receives splashes of a developing liquid or rinse agent, a developer nozzle 65 that supplies a developing agent to the wafer W, and a rinse nozzle 66 that supplies a rinse agent to the wafer W. The developing device 300′ is also provided with the third light source 1C that generates the auxiliary light R3, a third optical system 2C that guides the auxiliary light R3 emitted from the third light source 10 onto the wafer W, and a third exposure amount control unit 20C that controls exposure amount of the auxiliary light R3. The third exposure amount control unit 20C can control exposure amount of the auxiliary light R3 based on the exposure amount of the out-of-band light of the exposure light R1 and the exposure amount of the auxiliary light R2. At that time, the third exposure amount control unit 20C may control the exposure amount of the auxiliary light R3 such that the sum of the exposure amount of the out-of-band light of the exposure light R1 and the exposure amounts of the auxiliary lights R2 and R3 are kept constant. In addition, a light sensor 67 may be provided on the wafer holder 63 to detect the auxiliary light R3.

Then, the auxiliary light R3 emitted from the third light source 1C is projected onto the wafer W via the third optical system 2C. In this example, before the auxiliary light R3 is projected onto the wafer W, the third light source 10 and the third optical system 2C can be moved such that the auxiliary light R3 is projected onto the light sensor 67. Then, the light sensor 19 measures the exposure amount of the auxiliary light R3. The intensity and irradiation time of the auxiliary light R3 can be set to compensate for fluctuations in the exposure amount of the out-of-band light of the exposure light R1 detected by the light sensor 19.

When the auxiliary light R3 is irradiated to the wafer W, the wafer holder 63 is rotated via the motor 62 to rotate the wafer W. In some cases, however, the rotation process may not be performed. Then, when the developing agent is supplied from the developer nozzle 65 to the wafer W, the resist film R is developed. Next, when the rinse agent is supplied from the rinse nozzle 66 to the wafer W, the developing agent is flown out from the wafer W to stop the development.

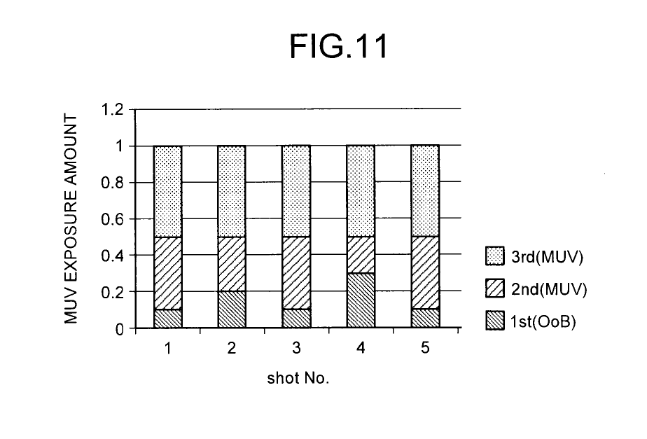

FIG. 11 is a diagram illustrating a setting method of auxiliary light with respect to out-of-band light according to the third embodiment.

Referring to FIG. 11, when the intensity of the out-of-band (OoB) light of the EUV light fluctuates depending on shot numbers, the exposure amounts of the MUV lights (second and third) at the exposure device 200 and the developing device 300′ can be set to compensate for the fluctuations, thereby reducing differences in measured dimension between shots. FIG. 11 recites a method of compensating for the fluctuations in the OoB light intensity depending on the shot numbers. However, the method is not limited to the compensation of differences between shots, and the method may compensate for differences in measured dimension in a shot, differences in measured dimension between wafers, or differences in measured dimension between lots. In that case, the exposure amount of the MUV lights at the exposure device 200 and the developing device 300′ can be set to compensate for fluctuations between lots, wafers, or shots, or fluctuations in a shot.

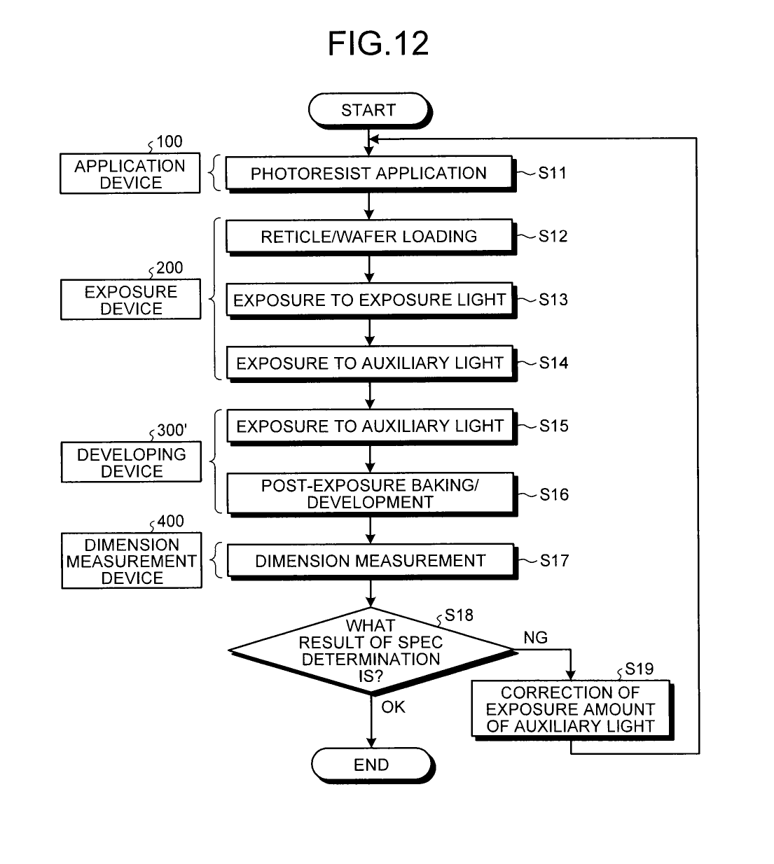

FIG. 12 is a flowchart of one example of a lithography process in which the EUV exposure method according to the third embodiment is used.

Referring to FIG. 12, a photoresist is applied to the wafer W at the application device 100 (S11). Then, the reticle 9 and the wafer W are loaded to the exposure device 200 (S12). Then, the exposure light R1 is irradiated to the photoresist on the wafer W by predetermined exposure amount to expose the photoresist on the wafer W (S13). In addition, the auxiliary light R2 is irradiated to the photoresist on the wafer W to compensate partly for fluctuations in the out-of-band light of the exposure light R1 (S14). Then, a developing device 300′ irradiates the auxiliary light R3 to the photoresist on the wafer W to compensate for fluctuations in the out-of-band light of the exposure light R1 (S15). Then, the developing device 300′ performs post-exposure baking and development to form a resist pattern on the wafer W (S16). Then, the dimension measurement device 400 measures a dimension of the resist pattern on the wafer W (S17). Then, it is determined whether the dimension of the resist pattern on the wafer W falls within a specified range (S18). When the dimension does not fall within the specified range, the exposure amount of the auxiliary light R3 is corrected (S19) and the process is returned to S11. Then, steps S11 to S18 are repeated until the dimension of the resist pattern on the wafer W falls within the specified range.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An exposure device, comprising:
a stage on which a substrate is placed;
a first light source that generates exposure light with a first wavelength belonging to an EUV band;
a second light source that generates, separately from the exposure light, auxiliary light with a second wavelength different from the first wavelength;
a first optical system that guides the exposure light to the substrate; and
a second optical system that guides the auxiliary light to the substrate.

2. The exposure device according to claim 1, comprising:
a first exposure amount control unit that controls exposure amount of the exposure light; and
a second exposure amount control unit that controls exposure amount of the auxiliary light.

3. The exposure device according to claim 2, wherein the exposure light contains out-of-band light with the second wavelength.

4. The exposure device according to claim 3, comprising a light sensor that detects the auxiliary light and the out-of-band light with the second wavelength on the stage.

5. The exposure device according to claim 4, wherein the second exposure amount control unit controls the exposure amount of the auxiliary light based on the exposure amount of the out-of-band light.

6. The exposure device according to claim 5, wherein the second exposure amount control unit controls the exposure amount of the auxiliary light so as to keep the sum of the exposure amount of the out-of-band light and the exposure amount of the auxiliary light constant.

7. The exposure device according to claim 1, wherein the auxiliary light is guided to the substrate via the second optical system and a part of the first optical system.

8. An exposure method by which to expose a resist film formed on a processing layer by irradiating exposure light with a first wavelength belonging to an EUV band and auxiliary light with a second wavelength different from the first wavelength, the auxiliary light being separately generated from the exposure light.

9. The exposure method according to claim 8, wherein the exposure light and the auxiliary light are simultaneously irradiated to the resist film.

10. The exposure method according to claim 8, wherein, after the exposure light is irradiated to the resist film, the auxiliary light is irradiated to the resist film.

11. The exposure method according to claim 8, wherein the exposure light and the auxiliary light are irradiated to the resist film on the stage.

12. The exposure method according to claim 8, wherein
the exposure light is irradiated to the resist film on a stage of an exposure device, and
the auxiliary light is irradiated to the resist film on a wafer holder of a developing device.

13. The exposure method according to claim 8, wherein
the exposure light and a part of the auxiliary light are irradiated to the resist film on a stage of an exposure device, and
a part of the auxiliary light is irradiated to the resist film on a wafer holder of a developing device.

14. The exposure method according to claim 8, wherein the exposure light contains out-of-band light with the second wavelength.

15. The exposure method according to claim 14, wherein exposure amount of the auxiliary light is controlled based on exposure amount of the out-of-band light.

16. The exposure method according to claim 8, wherein a first pattern provided on a first reticle corresponding to the exposure light and a second pattern provided on a second reticle corresponding to the auxiliary light are equal to a design pattern.

17. The exposure method according to claim 8, wherein the resist film is a photosensitized resist film.

18. The exposure method according to claim 8, wherein
the first pattern provided on the first reticle corresponding to the exposure light and the second pattern provided on the second reticle corresponding to the auxiliary light are different from each other, and
an overlapping portion between a region exposed to light via the first pattern and a region exposed to light via the second pattern is equal to a design pattern.

19. The exposure method according to claim 8, wherein the resist film grows acid by causing a photosensitizer generated based on the exposure light to selectively absorb the auxiliary light.

20. A manufacturing method of a semiconductor device, comprising the steps of:
exposing a resist film formed on a processing layer by irradiating exposure light with a first wavelength belonging to an EUV band and auxiliary light with a second wavelength different from the first wavelength, the auxiliary light being separately generated from the exposure light;
forming a resist pattern on the processing layer by developing the exposed resist film; and
processing the processing layer via the resist pattern.
